(19) United States
(12) Patent Application Publication
(10) Pub. No.: US 2025/0351595 A1
(43) Pub. Date: Nov. 13, 2025

(54) SEMICONDUCTOR IMAGE SENSOR DEVICE

(71) Applicant: UNIVERSITY OF MIYAZAKI, Miyazaki-shi, Miyazaki (JP)

(72) Inventors: Koji MORI, Miyazaki-shi (JP); Ayaki TAKEDA, Miyazaki-shi (JP); Takeshi TSURU, Kyoto-shi (JP); Ikuo KURACHI, Hachioji-shi (JP)

(21) Appl. No.: 18/869,736

(22) PCT Filed: Apr. 13, 2023
(86) PCT No.: PCT/JP2023/014999

§ 371 Date: Nov. 26, 2024

(30) Foreign Application Priority Data
May 30, 2022 (JP) 2022-088053

(51) Int. Cl. H10F 39/00; H10F 39/18

(52) U.S. Cl. CPC H10F 39/8037; H10F 39/026; H10F 39/189

(57) ABSTRACT

The semiconductor image sensor device includes: on a front surface side of the silicon support substrate, a first buried well layer that has the first impurity concentration at a first position and serves as a backgate of the MOS transistor element and a second buried well layer that has the first impurity concentration at a second position that is separated from the first position and does not face the backgate; a third buried well layer that has a second impurity concentration and is formed to be separated from the first buried well layer, be located near the second buried well layer, and surround the first buried well layer; and a fourth buried well layer that has a third impurity concentration and contacts with bottom surfaces of the first buried well layer and the third buried well layer.

### TECHNICAL FIELD

The present invention relates to a semiconductor image sensor device for detecting charged particles such as a rays and β rays and light including X rays, γ rays, ultraviolet rays, and infrared rays (hereinafter, referred to as charged particles and light).

### BACKGROUND ART

In a semiconductor image sensor device, a photodiode for detecting charged particles and light and a transistor element are typically formed on the same semiconductor substrate.

As this type of semiconductor image sensor device, a device using a silicon on insulator (SOI) with an insulating layer of an oxide film or the like which is so-called buried oxide (BOX) buried in a silicon substrate is typically known.

FIG. 4 is a sectional view illustrating a basic configuration of a semiconductor image sensor device using an SOI layer.

A photodiode that detects charged particles and light is formed inside a first silicon substrate 401, and a processing circuit including a transistor element that amplifies and processes a detected signal is formed in a second silicon layer 402 separated by a buried oxide film layer 403.

A fill factor of the photodiode with respect to a unit pixel is sufficiently increased in size and a circuit of a certain size can be disposed within a pixel that is a pixel unit by employing such a structure.

In a case where a conductivity type of the first silicon substrate 401 is a P type, for example, the photodiode can be realized as a PN junction diode by ion implantation of a desired dose of donor impurities such as phosphorus and forming a diffusion layer 404 on the lower surface of the buried oxide film layer 403 of the first silicon substrate 401 as an N type.

Note that the reference sign 405 denotes a gate electrode of the transistor element formed in the second silicon layer 402, the reference sign 406 denotes an interlayer insulating film, and the reference sign 407 denotes a metal wiring.

Here, if a reverse bias is applied between the diffusion layer 404 and the first silicon substrate 401 in order to form a depletion layer to detect charged particles and light, the depletion layer spreads in the first silicon substrate 401 and the diffusion layer 404 as illustrated by the dashed line in the drawing. The depletion layer extends along an interface between the buried oxide film layer 403 and the first silicon substrate 401 at the interface. Since an interface state is present at the interface, a leakage current flows via the interface state, and this serves as a current at a dark time (dark current) and degrades sensor properties. Also, a high voltage is applied to the first silicon substrate 401 in order to enhance sensitivity of detection of charged particles and light. In that case, since the first silicon substrate 401 serves as a backgate of the transistor element formed in the second silicon layer 402, properties of the transistor element may change due to the applied voltage, and an operation error of a processing circuit configured of the transistor element may occur.

Therefore, structural arrangements of (1) preventing the depletion layer from extending as much as possible along the interface between the first silicon substrate 401 and the buried oxide film layer 403 and (2) suppressing a backgate effect of the transistor element formed in the second silicon layer 402 are needed in the configuration of the semiconductor image sensor device.

Furthermore, in order to (3) improve sensor sensitivity, a structural arrangement therefor is also needed because it is desirable to fully deplete and use a PN junction surface of the photodiode for detection.

As prior art documents that implement the above structural arrangements, Patent Documents 1 to 3 below are known.

FIG. 5 is a sectional configuration diagram of a semiconductor device described in Patent Document 1 in which a photodiode and a transistor element are formed on the same semiconductor substrate via an insulating film. In a semiconductor device (100), a buried well (14) formed of impurities of a conductivity type opposite to that of a sense node (182) of PN junction which is a photodiode (30) is formed at a lower portion of a transistor circuit (40), and the backgate effect is suppressed by fixing a potential in a region serving as a backgate. Also, the buried well (14) is located near the photodiode (30) in order to prevent a depletion layer from extending along an interface.

However, the structure has a disadvantage that since the buried well (14) is connected to a sense node (182), the parasitic capacitance of the sense node (182) increases, and sensitivity of the photodiode (30) is degraded.

FIG. 6 is a sectional configuration diagram of a semiconductor device described in Patent Document 2.

In the semiconductor device, the backgate effect is suppressed by fixing a potential of a first buried well (14) formed at a lower portion of a transistor circuit (40) and serving as a backgate.

Furthermore, a region including the first buried well (114) is surrounded and separated by second buried wells (116, 118, 119) of a conductivity type opposite to that of a substrate (11).

In this manner, the width of a depletion layer spreading between the second buried wells (116, 118, 119) and the first buried well (114) is increased, and the parasitic capacitance is thus reduced.

Furthermore, since the depletion layer of the photodiode (30) is formed to extend along an interface (151) in the structure, the dark current is not reduced. Since conductivity types of a sensor node (232) and the second buried wells (116, 118, 119) are the same, a carrier generated due to a photoelectric effect in the photodiode (30) is absorbed not only by the sense node (232) but also the second buried wells (116, 118, 119). Therefore, there is a disadvantage that sensitivity is degraded.

FIG. 7 is a sectional configuration diagram of a semiconductor device described in Patent Document 3.

A semiconductor device (11) includes a p-type electrode (24) that is formed on a support substrate (14) in contact with a second surface facing a first surface of a BOX layer (20) in contact with an SOI substrate (22) and is provided in a second region that is different from a first region corresponding to an element region, a p-type hole accumulation layer (18) that is provided in a region including at least a partial region formed on the support substrate (14) in contact with the second surface of the BOX layer (20), which is a region covering the first region and the electrode (24), the potential of the hole accumulation layer (18) being neutralized, an n-type detection electrode (30) that is formed on the support substrate (14) in contact with the second surface of the BOX layer (20), and an n-type potential barrier layer (16) that is provided between the support substrate (14) and the second surface of the BOX layer (20) at a part where the electrode (24) formed on the support substrate (14) in contact with the second surface of the BOX layer (20), the hole accumulation layer (18), and a detection electrode (30) are provided and forms a potential barrier.

In the structure, a depletion layer extending at the interface is minimized, and a backgate formed below a pixel circuit (50) can also be fixed with the potential of the hole accumulation layer (18) which is a buried well.

However, a leaking current is likely to pass through the potential barrier layer (16) from the hole accumulation layer (18) and flow through the support substrate (14) in the structure, and it is necessary to set a sufficiently high impurity concentration in the potential barrier layer (16) to prevent this. Also, since conductivity types of the potential barrier layer (16) and the detection electrode (30) are the same, there is a likelihood of leakage between adjacent pixels.

Moreover, separation of adjacent pixels by the potential barrier layer (16) is achieved by fully depleting the inside of the potential barrier layer (16) by a depletion layer formed in the potential barrier layer (16) by setting a reverse bias between the hole accumulation layer (18) and the potential barrier layer (16) and between the support substrate (14) and the potential barrier layer (16).

Therefore, there is a defect that a bias voltage to be applied to the hole accumulation layer (18) and the support substrate (14) is limited.

### CITATION LIST

### Patent Document

Patent Document 1: Japanese Unexamined Patent Application, First Publication No. 2013-69924

Patent Document 2: Japanese Unexamined Patent Application, First Publication No. 2014-130920

Patent Document 3: Japanese Unexamined Patent Application, First Publication No. 2019-106519

### SUMMARY OF INVENTION

### Technical Problem

The present invention has been made in view of the aforementioned related art, and an object thereof is to provide a semiconductor image sensor device that can suppress generation of a leakage current due to an interface state, can easily achieve full depletion even if a limit of a voltage to be applied to a support substrate is alleviated, and does not degrade sensitivity of a photodiode formed in the support substrate.

### Solution to Problem

FIG. 1 illustrates a semiconductor image sensor device according to the present invention. The semiconductor image sensor device according to the present invention is a semiconductor image sensor device, in which an SOI layer (110) and a silicon support substrate (11) is stacked, the SOI layer (110) contacting a first surface of an insulating layer (107) and including an MOS transistor element (114) making up a pixel circuit, the silicon support substrate (101) contacting a second surface facing the first surface of the SOI layer (110) and having a first impurity concentration of a first conductivity type, a photodiode to detect charged particles and light being formed in the silicon support substrate (110), the semiconductor image sensor device comprising:
in a region (P) corresponding to one pixel,
on a front surface side of the silicon support substrate (101),
i: a first buried well layer (102-1) that has the first impurity concentration of a second conductivity type at a first position (A) that is in contact with the second surface of the insulating layer (107) and serves as a backgate of the MOS transistor element (114) and a second buried well layer (102-2) that has the first impurity concentration of the second conductivity type at a second position (B) that is separated from the first position (A) and does not face the backgate;
ii: a third buried well layer (103) that has a second impurity concentration of the first conductivity type and is formed to be separated from the first buried well layer (102-1) in a first direction and a second direction by a predetermined distance, be located near the second buried well layer (102-2), and surround the first buried well layer (102-1) from both sides;
iii: a fourth buried well layer (104) that has a third impurity concentration of the first conductivity type and is formed to be in contact with bottom surfaces of the first buried well layer (102-1) and the third buried well layer (103) at a deeper position than the first buried well layer (102-1); and
iv. a diffusion layer for contact (105) that has the second impurity concentration of the second conductivity type and is formed at a desired position in the first buried well layer (102-1) and the second buried well layer (102-2), wherein
on a side of a rear surface of the silicon support substrate (101), and wherein
v: a rear diffusion layer (106) that has a fourth impurity concentration of the first conductivity type and is formed,
a potential (VBB) necessary to fully deplete the silicon support substrate (101) is applied between the diffusion layer for contact (105) of the first buried well layer (102-1) and the rear diffusion layer (106), and
the diffusion layer for contact (105) of the second buried well layer (102-2) is used as a mechanism that transmits, to the MOS transistor element (114) a signal generated with detection of charged particles and light in a depletion layer of the silicon support substrate (101).

In the semiconductor image sensor device according to the present invention, the first conductivity type is a P type, the first impurity concentration of the silicon support substrate (101) falls within a range of 1×10¹² cm⁻³ to 1×10¹⁴ cm⁻in terms of dopant concentration, the second impurity concentration of the third buried well layer (103) is a concentration defined by an ion implantation energy of 110 eV to 150 eV and with a dose in a range of 1×10¹² cm⁻² to 5×10¹³ cm⁻², the third impurity concentration of the fourth buried well layer (104) is a concentration defined by an ion implantation energy of 360 eV to 400 eV and with a dose in a range of 1×10¹² cm⁻² to 5×10¹³ cm⁻², and the fourth impurity concentration of the rear diffusion layer (106) is a concentration that is higher than the third impurity concentration, and
the second conductivity type is an N type, the first impurity concentration of the first buried well layer (102-1) and the second buried well layer (102-2) is a concentration defined by an ion implantation energy of 280 eV to 320 eV and with a dose in a range of 0.5×10¹² cm⁻² to 5×10¹³ cm², and the second impurity concentration of the diffusion layer for contact (105) is a concentration defined by an energy of 10 eV to 50 eV and with a dose in a range of 1×10¹⁵ cm⁻² to 1×10¹⁶ cm⁻².

Furthermore, in the semiconductor image sensor device according to the present invention, the silicon support substrate (101) has a thickness of 700 μm to 800 μm, the insulating layer (107) has a thickness of 10 nm to 200 nm, and the SOI layer (110) has a thickness of 10 nm to 1000 nm.

### Advantageous Effects of Invention

According to the structure of the present invention, in a case of a pixel size of 20×20 μ², for example, it is possible to reduce the area in which the depletion layer comes into contact with the interface between the silicon support substrate 101 and the insulating layer 107 to about 7% and also to reduce a dark current to about 7% with respect to the ordinary structure illustrated in FIG. 4. Furthermore, since all electrons generated in the depletion layer formed in the silicon support substrate 101 by the photodiode can be collected in the second buried well layer 102-2 that serves as a detection node, it is thus possible to achieve a sensor with high sensitivity. Moreover, the second buried well layer 102-2 suppressing formation of a surface depletion layer can also be used as an electrode capable of suppressing the backgate effect of the MOS transistor element 114, and it is possible to guarantee a stable operation. In terms of the structure, since it is only necessary to form two types of buried well layers in the silicon support substrate 101 where the photodiode is formed in practice, the number of processes to be added is small, which also leads to manufacturing cost reduction.

Therefore, it is possible to realize a semiconductor image sensor device that suppresses generation of a leakage current due to an interface state, can easily achieve full depletion even if a limit of a voltage to be applied to a support substrate is alleviated, and does not degrade sensitivity of a photodiode formed in the support substrate.

### BRIEF DESCRIPTION OF DRAWINGS

FIG. 1A sectional configuration diagram of a semiconductor image sensor device according to an embodiment of the present invention.

FIG. 2A A sectional view for each manufacturing process for explaining a method of manufacturing the semiconductor image sensor device according to the present invention (part 1).

FIG. 2B A sectional view for each manufacturing process for explaining the method of manufacturing the semiconductor image sensor device according to the present invention (part 2).

FIG. 2C A sectional view for each manufacturing process for explaining the method of manufacturing the semiconductor image sensor device according to the present invention (part 3).

FIG. 2D A sectional view for each manufacturing process for explaining the method of manufacturing the semiconductor image sensor device according to the present invention (part 4).

FIG. 2E A sectional view for each manufacturing process for explaining the method of manufacturing the semiconductor image sensor device according to the present invention (part 5).

FIG. 2F A sectional view for each manufacturing process for explaining the method of manufacturing the semiconductor image sensor device according to the present invention (part 6).

FIG. 2G A sectional view for each manufacturing process for explaining the method of manufacturing the semiconductor image sensor device according to the present invention (part 7).

FIG. 2H A sectional view for each manufacturing process for explaining the method of manufacturing the semiconductor image sensor device according to the present invention (part 8).

FIG. 2 A sectional view for each manufacturing process for explaining the method of manufacturing the semiconductor image sensor device according to the present invention (part 9).

FIG. 2J A sectional view for each manufacturing process for explaining the method of manufacturing the semiconductor image sensor device according to the present invention (part 10).

FIG. 2K A sectional view for each manufacturing process for explaining the method of manufacturing the semiconductor image sensor device according to the present invention (part 11).

FIG. 3 A concentration profile obtained through simulations of a buried well layer produced according to the present invention.

FIG. 4 A sectional view illustrating a basic configuration of a semiconductor image sensor device using an SOI layer.

FIG. 5 A sectional configuration diagram of a semiconductor device described in Patent Document 1.

FIG. 6 A sectional configuration diagram of a semiconductor device described in Patent Document 2.

FIG. 7 A sectional configuration diagram of a semiconductor device described in Patent Document 3.

### DESCRIPTION OF EMBODIMENTS

First, a configuration of a semiconductor image device according to an embodiment of the present invention will be described.

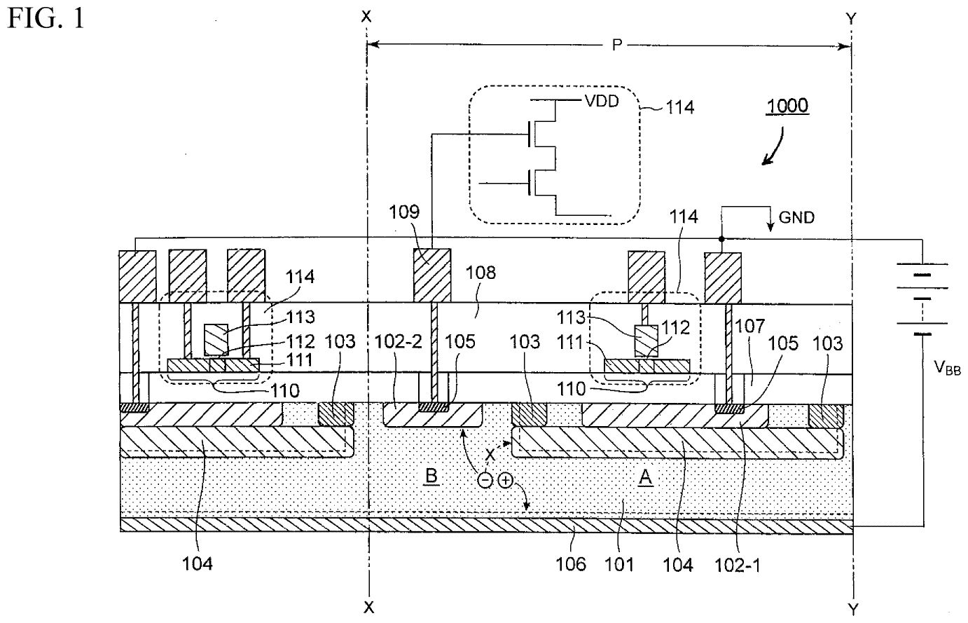

FIG. 1 illustrates a sectional structure of a region P corresponding to one pixel of an image sensor. The region P is a region sandwiched by the line X-X and the line Y-Y in the drawing and repeatedly appears in a first direction (left direction) and a second direction (right direction) in FIG. 1 at the same pitch.

Also, such pixels are two-dimensionally arranged to thereby form an imaging region of a semiconductor image sensor. Here, the pixels have a function of detecting charges generated in the pixels and performs time-domain modulation and are called lock-in pixels.

As illustrated in FIG. 1, a semiconductor image sensor device 1000 according to the present embodiment is adapted such that a silicon on insulator (SOI) layer 110 with an MOS transistor element 114 that configures a pixel circuit is stacked on a silicon support substrate 101 including a first impurity concentration of a first conductivity type via an insulating layer 107 that is called a buried oxide (BOX) layer.

Note that a plurality of MOS transistor elements 114 that configure the pixel circuit are included in the configuration, FIG. 1 illustrates only one transistor element as a representative, 112 denotes a gate insulating film, and 113 denotes a gate electrode.

On a front surface side of the silicon support substrate 101, a first buried well layer 102-1 that has a first impurity concentration of a second conductivity type at a position A that is in contact with the insulating layer 107 and serves as a backgate of the MOS transistor element 114 is formed. Furthermore, a second buried well layer 102-2 that has the first impurity concentration of the second conductivity is also formed at a position B that is separated from the position A and does not face the backgate.

A third buried well layer 103 that has a second impurity concentration of a first conductivity type is formed at a position that is separated from the first buried well layer 102-1 by a predetermined distance in the first direction and the second direction (left and right) and is located near the second buried well layer 102-2 so as to surround the first buried well layer 102-1 from both sides.

Furthermore, a fourth buried well layer 104 that has a third impurity concentration of the first conductivity type is formed at a deeper position than the first buried well layer 102-1 so as to be in contact with bottom surfaces of the first buried well layer 102-1 and the third buried well layer 103.

A diffusion layer 105 for contact that has the second impurity concentration of the second conductivity type is formed at a desired position in the first buried well layer 102-1 and the second buried well layer 102-2.

A rear diffusion layer 106 that has a fourth impurity concentration of the first conductivity type is formed on a side of a rear surface of the silicon support substrate 101.

A potential V_{BB} necessary to fully deplete the silicon support substrate 101 is applied between the diffusion layer for contact 105 and the rear diffusion layer 106 of the first buried well layer 102-1.

The diffusion layer for contact 105 of the second buried well layer 102-2 is used as a mechanism to transmit, to the MOS transistor element 114, a signal generated with detection of charged particles and light in a depletion layer of the silicon support substrate 101. Note that 108 denotes an interlayer insulating film and 109 denotes a metal wiring.

Here, the first conductivity type is a P type, the first impurity concentration of the silicon support substrate 101 falls within a range of 1×10¹² cm⁻³ to 1×10¹⁴ cm⁻³ in terms of dopant concentration, the second impurity concentration of the third buried well layer 103 is a concentration defined by an ion implantation energy of 110 eV to 150 eV and with a dose in a range of 1×10¹² cm⁻² to 5×10¹³ cm⁻², the third impurity concentration of the fourth buried well layer 104 is a concentration defined by an ion implantation energy of 360 eV to 400 eV and with a dose in a range of 1×10¹² cm⁻² to 5×10¹³ cm⁻², and the fourth impurity concentration of the rear diffusion layer 106 is a concentration that is higher than the third impurity concentration, the second conductivity type is an N type, the first impurity concentration of the first buried well layer 102-1 and the second buried well layer 102-2 is a concentration defined by an ion implantation energy of 280 eV to 320 eV and with a dose in a range of 0.5×10¹² cm⁻² to 5×10¹³ cm⁻², and the second impurity concentration of the diffusion layer for contact 105 is a concentration defined by an energy of 10 eV to 50 eV and with a dose in a range of 1×10¹⁵ cm⁻² to 1×10¹⁶ cm⁻².

Also, the silicon support substrate 101 has a thickness of 700 μm to 800 μm, the insulating layer 107 has a thickness of 10 nm to 200 nm, and the SOI layer 110 has a thickness of 10 nm to 1000 nm.

In the semiconductor image sensor illustrated in FIG. 1, the second buried well layer 102-2 functions as a sense node that collects carriers and is formed in a minimum dimension that is allowable in the semiconductor manufacturing technology. Therefore, the parasitic capacitance of the sense node is suppressed to a low parasitic capacitance, and high sensitivity is realized. Also, the first buried well layer 102-1 of the same conductivity type is formed at a distance, with which pressure resistance can be sufficiently secured, from the second buried well layer 102-2, an area in which a depletion layer (illustrated by a dotted line in the drawing) extending from a PN junction of a photodiode is in contact with an interface between the silicon support substrate 101 and the insulating layer 107 is minimized, and generation of a dark current is suppressed.

Since the third buried well layer 103 and the fourth buried well layer 104 with an opposite conductivity type are formed to surround the first buried well layer 102-1, carriers generated due to a photoelectric effect of charged particles and light in the depletion layer of the photodiode are not collected by the third buried well layer 103 and the fourth buried well layer 104 as illustrated in the drawing, all the carriers are connected by the second buried well layer 102-2 serving as a sense node, and degradation of detection sensitivity is thus prevented.

Note that the silicon support substrate 101 is preferably a P-type silicon substrate with a very low dopant concentration (1×10¹² cm⁻³ to 1×10¹⁴ cm⁻³) in order to deplete the depletion layer as wide as possible, preferably fully deplete the depletion layer. The second buried well layer 102-2 serving as a sense node is formed as an N-type diffusion layer with a concentration at an intermediate level (1×10¹⁵ cm⁻³ to 1×10¹⁸ cm⁻³). Furthermore, the diffusion layer for contact 105 with a high concentration (1×10¹⁸ cm⁻³ to 1×10²¹ cm⁻³) is disposed in the second buried well layer 102-2.

Also, ohmic connection with the metal wiring 109 via the diffusion layer for contact 105 is enabled.

Furthermore, the first N-type buried well layer 102-1 with an intermediate concentration (1×10¹⁵ cm⁻³ to 1×10¹⁸ cm⁻³) is disposed in order to avoid the depletion layer extending at the interface between the silicon support substrate 101 and the insulating layer 107 to reduce a dark current. The first N-type buried well layer 102-1 serves as an electrode suppressing a backgate effect of the MOS transistor element 114 formed in the SOI layer 110, and it is thus possible to fix the first N-type buried well layer 102-1 at a fixed potential, or a ground (GND) level in many cases.

If the desired voltage V_{BB} is applied between the first buried well layer 102-1 and the rear diffusion layer 106 in this state, the depletion layer spreads as surrounded by the dotted line in FIG. 1.

At this time, some electrons are collected by the second buried well layer 102-2 serving as a detection node and others may be collected by the first buried well layer 102-1 from among electron-hole pairs generated in the depletion layer. In this case, there is a concern of degradation of detection sensitivity. In the present invention, it is possible to separate the depletion layer from the first buried well layer 102-1 other than the detection node from the depletion layer from the second buried well layer 102-2 serving as the detection node as illustrated by the dotted line by disposing the P-type fourth buried well layer 104 and the P-type third buried well layer 103 formed at deeper positions than the first buried well layer 102-1 to suppress the degradation of sensitivity.

Also, since all electrons (−) generated in the depletion layer inside the silicon support substrate 101 are collected by the second buried well layer 102-2 serving as the detection node, it is possible to maintain high sensitivity to charged particles and light while suppressing generation of a dark current.

Note that although the P type is used for the silicon support substrate 101 in the aforementioned embodiment, it is only necessary to set the conductivity type of the buried well layer to the P type in a case where an N type is used for the silicon support substrate 101.

Next, a method of manufacturing the semiconductor image sensor device according to the present invention will be described.

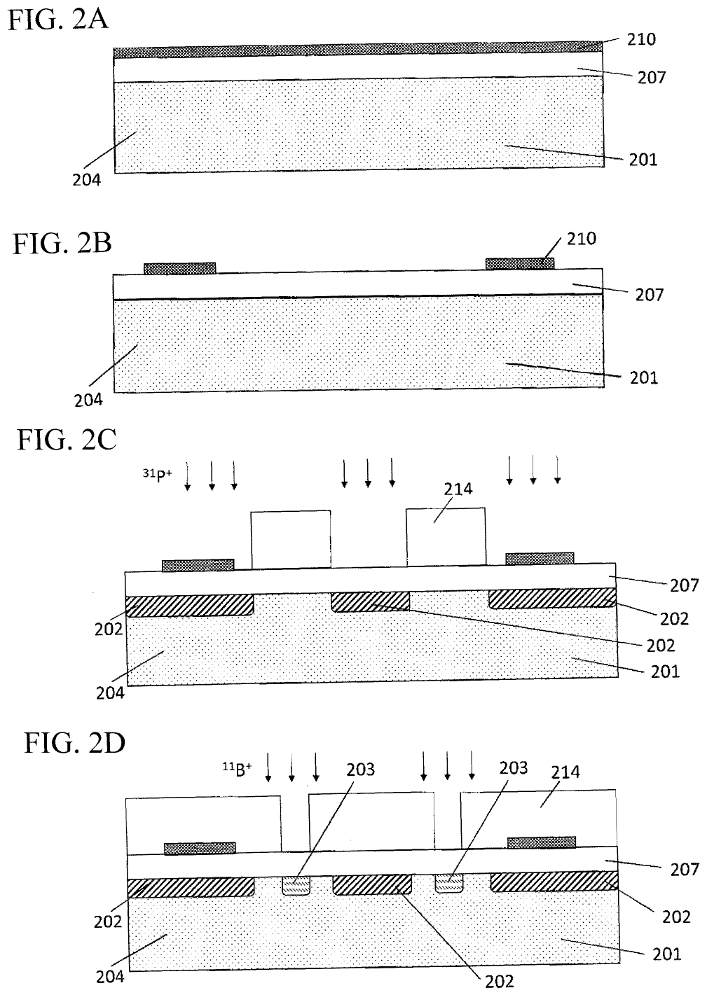

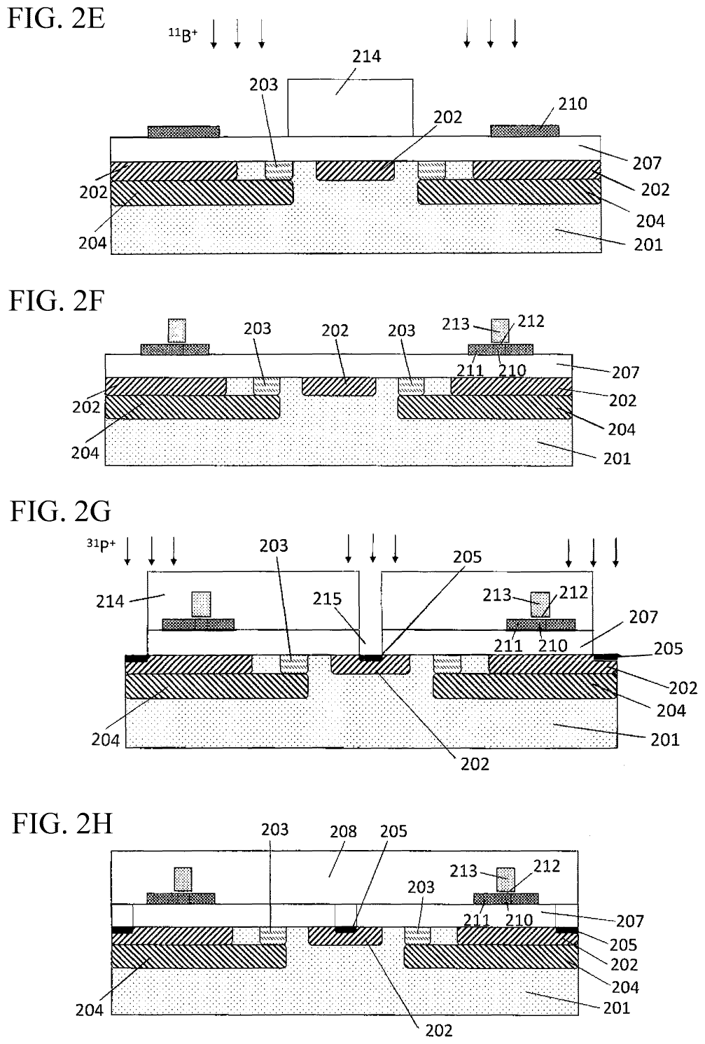

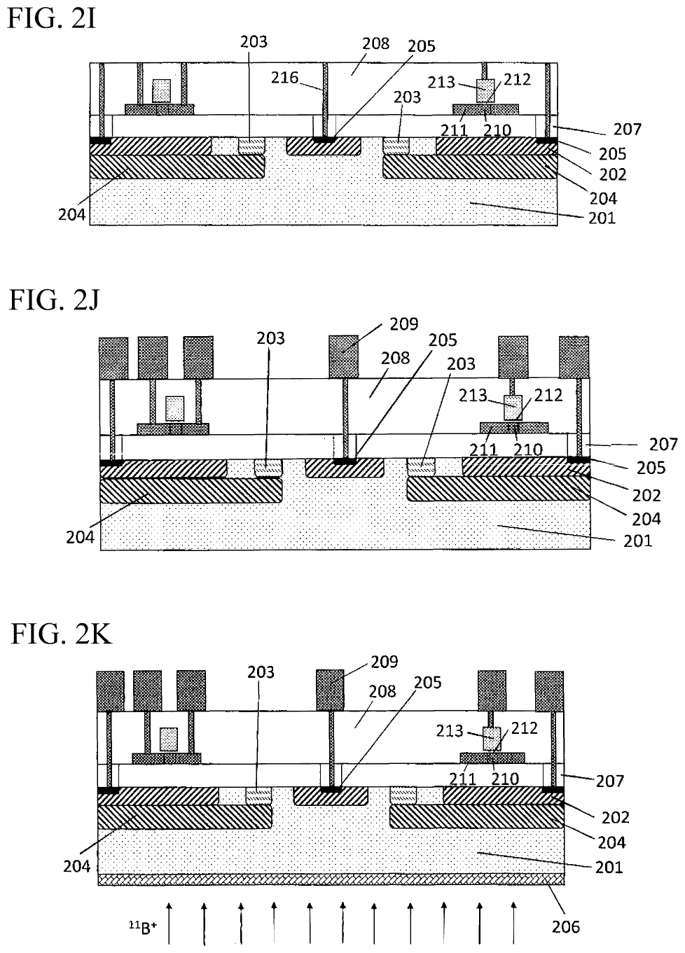

The semiconductor image sensor device according to the present invention illustrated in FIG. 1 is manufactured in accordance with a manufacturing method for each process illustrated in FIGS. 2(1) to 2(11).

An initial material for the manufacturing is an ordinary SOI wafer illustrated in FIG. 2A. In the SOI wafer, an oxide film layer 207 of 10 nm to 200 nm is formed on a P-type substrate 201 with a thickness of 700 μm to 800 μm and an extremely low concentration (1×10¹² cm⁻³ to 1×10¹⁴ cm⁻³), and furthermore, a silicon layer 210 of 10 nm to 1000 nm is formed thereon. At this time, any dopant concentration may be adopted for the silicon layer 210 as an upper layer.

The silicon layer 210 is patterned as illustrated in FIG. 2B by LOCOS or an STI method, which is a known element separation method. Thereafter, a photoresist 214 is formed in a region where a buried N well layer 202 is not formed by a known photolithography technology in order to form the buried N well layer 202, and phosphorus is implanted by using the photoresist 214 as a mask as illustrated in FIG. 2C. Implantation conditions are energy of 280 KeV to 320 KeV, and desirably 300 KeV and a dose of 0.5×10¹² cm⁻² to 5×10¹³ cm⁻², desirably 1.0×10¹² cm⁻². After the ion implantation, the photoresist 214 is removed.

Similarly, ion implantation of boron using the known photolithography technology and the photoresist 214 as a mask is performed to form a buried P well layer 203 as illustrated in FIG. 2D. The implantation conditions are energy of 110 KeV to 150 KeV, desirably 130 KeV and a dose of 1×10¹² cm⁻² to 5×10¹³ cm⁻², desirably 5×10¹² cm⁻². After the ion implantation, the photoresist 214 is removed. Furthermore, ion implantation of boron using the known photolithograph technology and the photoresist 214 a mask is performed to form a buried P well layer 204 as illustrated in FIG. 2E. The implantation condition is energy of 360 KeV to 400 KeV, desirably 380 KeV and a dose of 1×10¹² cm⁻² to 5×10¹³ cm⁻², desirably 5×10¹² cm⁻² in order to form it at a deeper part than the buried N well layer 202. After the ion implantation, the photoresist 214 is removed.

At this time, the ion injection conditions for the buried P well layer 203 and the buried P well layer 204 are adjusted such that the buried P well layer 203 and the buried P well layer 204 can be connected at a higher concentration than the concentration of the silicon support substrate 201. Thereafter, the processing proceeds to a process of manufacturing a MOSFET. As illustrated in FIG. 2F, an oxide film to serve as a gate insulating film 212 is formed into 1 nm to 5 nm by oxidizing the SOI layer 210 in an oxidation atmosphere at 700° C. to 900° C. first, polysilicon to serve as a gate electrode is deposited on the entire surface in 100 nm to 300 nm, and phosphorus or the like is doped to reduce the resistance. Furthermore, the polysilicon is patterned by known photolithography and etching to thereby obtain a gate electrode 213.

The MOSFET is completed by performing ion implantation of impurities of Group V such as arsenic to an N-type MOSFET or performing ion implantation of impurities of Group III such as boron to a P-type MOSFET using the gate electrode 213 as a mask to thereby form a diffusion layer 211 to serve as a source and a drain of the MOSFET. At this time, the MOSFET is disposed on the buried N well layer 202, and the buried N well layer 202 functions as a backgate of the MOSFET.

In a next process, an opening portion is formed in the buried oxide film layer 207 using the known photolithography technology and etching technology as illustrated in FIG. 2G in order to form a high concentration N+ layer 205 in the detection node. The reason that high-current ion implantation device is used to form a high-concentration diffusion layer in the opening is to prevent the buried oxide film 207 from being not implanted into silicon when the buried oxide film 207 is as thick as 100 nm to 200 nm since the implantation energy is limited in this case.

Next, phosphorus is ion-implanted to the opening portion using the buried oxide film 207 as a mask. The implantation conditions are energy of 10 KeV to 50 KeV, desirably 30 KeV and a dose of 1×10¹⁵ cm⁻² to 1×10¹⁶ cm⁻², desirably 5×10¹⁵ cm⁻². After the ion implantation, heat treatment to activate ion-implanted impurities including the buried well is performed a 900° C. to 1100° C., desirably 1000° C. for 10 to 100 seconds, desirably rapid thermal annealing for 30 seconds is performed.

Furthermore, the interlayer insulating film 208 is deposited in about 500 nm to 700 nm as illustrated in FIG. 2H. In order to establish electrical contact with the detection node, a contact is formed by the known photolithography technology and the etching technology, formation of a barrier metal, which is not illustrated, and deposition of tungsten in the contact are performed, extra tungsten deposited on the upper portion of the interlayer insulating film 208 is removed by chemical mechanical polishing (CMP), thereby forming a contact buried with tungsten as illustrated in FIG. 2I.

Furthermore, in order to electrically transmit a signal of the detection node, the metal wiring 209 is formed by ordinary aluminum sputtering, photolithography, and etching technologies as illustrated in FIG. 2J. Although not illustrated in the drawing, a wiring layer as an upper layer is formed through formation of an insulating film layer, formation of a via hole, and formation of a metal wiring, and formation of a protective film and pad opening are then performed as needed. Furthermore, after grinding the rear surface, formation of a high-concentration P+ layer 206 of the rear surface is performed by ion implantation and laser annealing from the rear surface as illustrated in FIG. 2K.

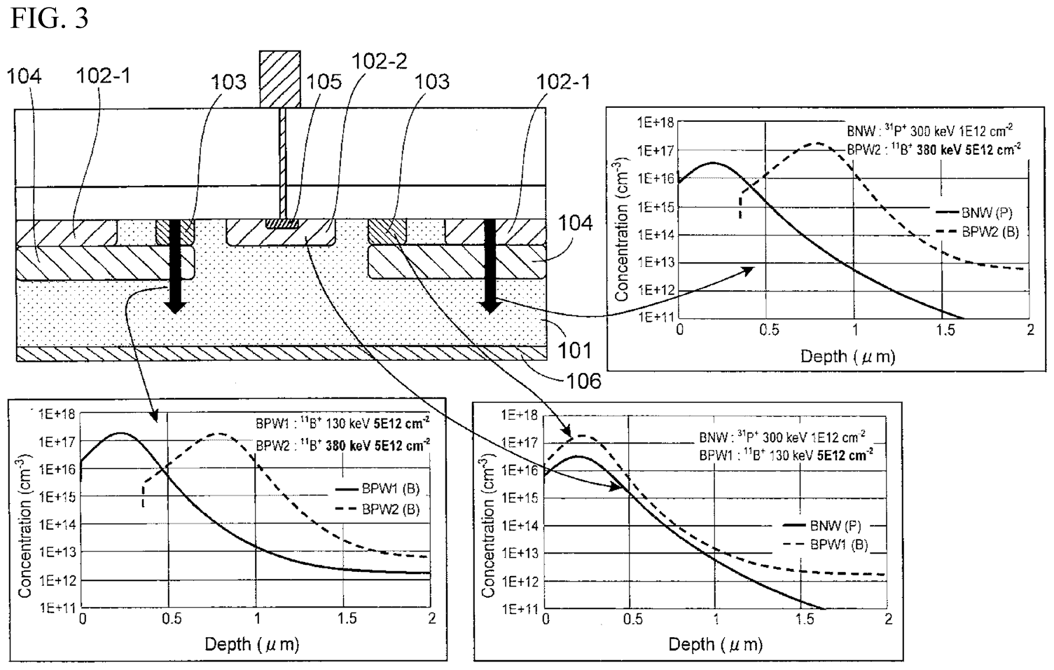

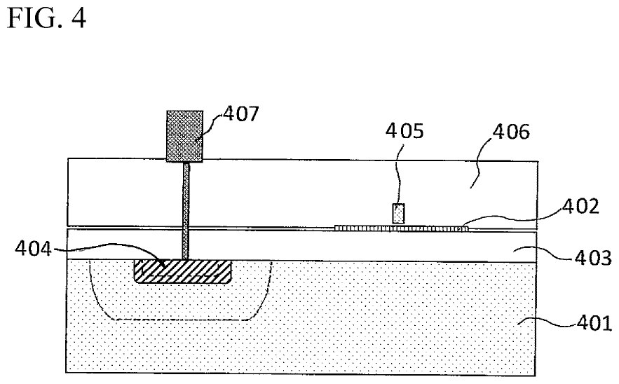

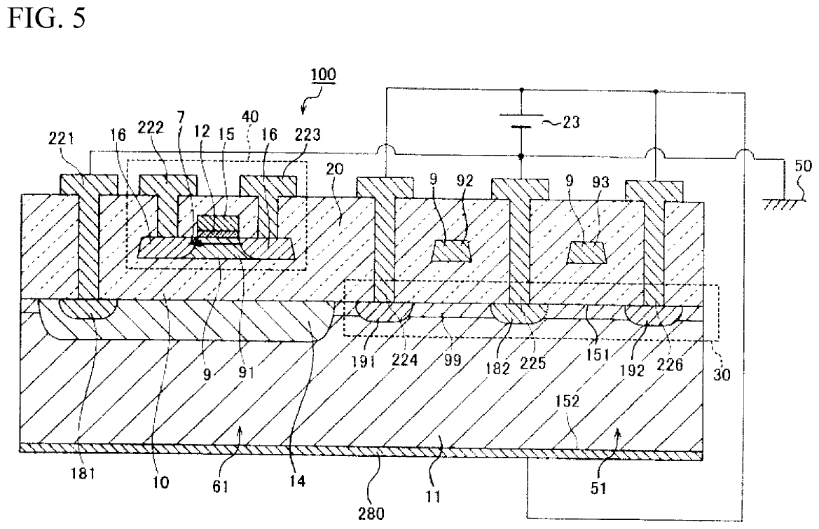

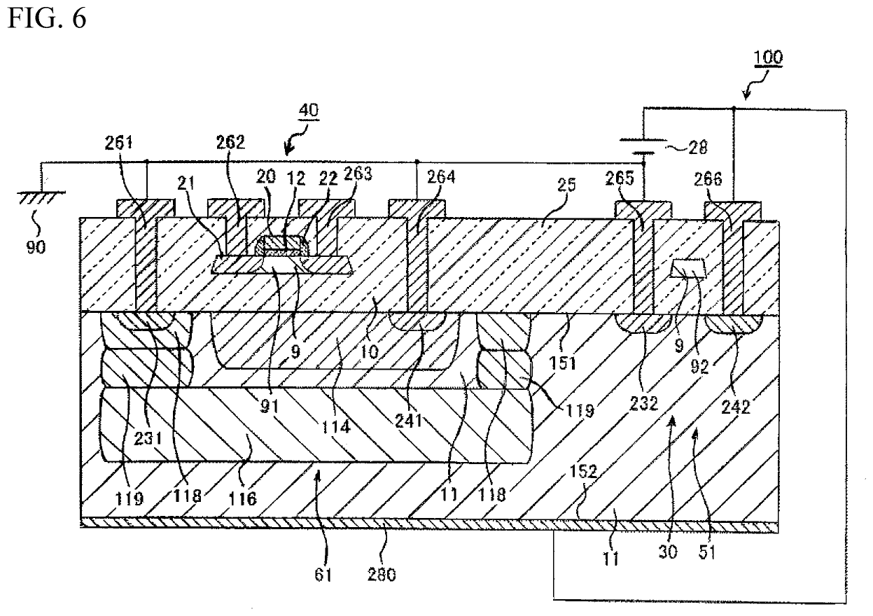

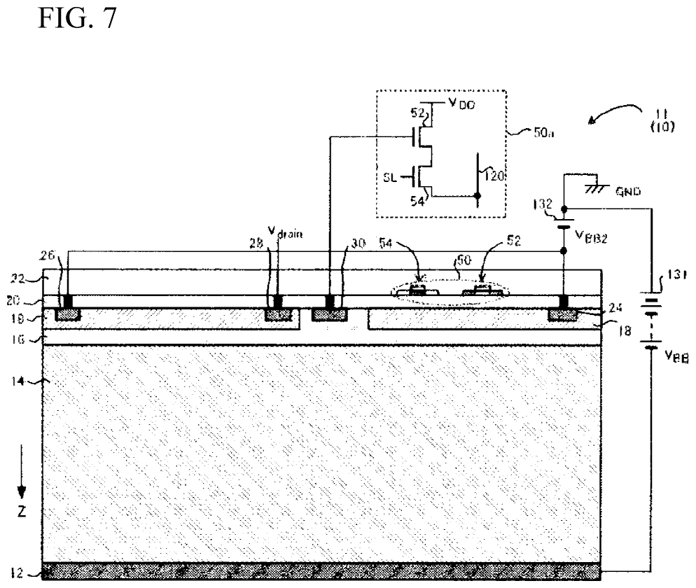

A concentration profile (based on simulations) at each main location obtained by the manufacturing method under the recommended conditions is shown in FIG. 3. The buried N well 102-1 is reliably formed, and the buried P well 104 serving as an electron barrier is formed at a lower portion thereof. Furthermore, the buried P wells 103 and 104 are in contact at a sufficiently higher concentration than the substrate concentration. In addition, profiles of the buried N well 102-1 and the buried P well 104 in the depth direction are similar, and it is possible to confirm that the target structure has been realized.

### REFERENCE SIGNS LIST

101 First silicon support substrate
102-1 First buried well layer, first N-type buried well layer
102-2 Second buried well layer
103 Third buried well layer, P-type third buried well layer
104 Fourth buried well layer, P-type fourth buried well layer
105 Diffusion layer for contact
106 Rear diffusion layer
110 SOI layer
114 MOS transistor element

1. A semiconductor image sensor device, in which an SOI layer and a silicon support substrate is stacked, the SOI layer contacting a first surface of an insulating layer and including an MOS transistor element making up a pixel circuit, the silicon support substrate contacting a second surface facing the first surface of the SOI layer and having a first impurity concentration of a first conductivity type, photodiodes to detect charged particles and light being formed in the silicon support substrate, the semiconductor image sensor device comprising:
on a front surface side of the silicon support substrate,
i: a first buried well layer that has the first impurity concentration of a second conductivity type at a first position that is in contact with the second surface of the insulating layer and serves as a backgate of the MOS transistor element and a second buried well layer that has the first impurity concentration of the second conductivity type at a second position that is separated from the first position and does not face the backgate;
ii: a third buried well layer that has a second impurity concentration of the first conductivity type and is formed to be separated from the first buried well layer in a first direction and a second direction by a predetermined distance, be located near the second buried well layer, and surround the first buried well layer from both sides;
iii: a fourth buried well layer that has a third impurity concentration of the first conductivity type and is formed to be in contact with bottom surfaces of the first buried well layer and the third buried well layer at a deeper position than the first buried well layer; and
iv. a diffusion layer for contact that has the second impurity concentration of the second conductivity type and is formed at a desired position in the first buried well layer and the second buried well layer, wherein
on a side of a rear surface of the silicon support substrate,
v: a rear diffusion layer that has a fourth impurity concentration of the first conductivity type and is formed, and wherein
a potential (V_{BB}) necessary to fully deplete the silicon support substrate is applied between the diffusion layer for contact of the first buried well layer and the rear diffusion layer, and
the diffusion layer for contact of the second buried well layer is used as a mechanism that transmits, to the MOS transistor element a signal generated with detection of charged particles and light in a depletion layer of the silicon support substrate.

2. The semiconductor image sensor device according to claim 1,
wherein the first conductivity type is a P type, the first impurity concentration of the silicon support substrate falls within a range of 1×10¹² cm⁻³ to 1×10¹⁴ cm⁻³ in terms of dopant concentration, the second impurity concentration of the third buried well layer is a concentration defined by an ion implantation energy of 110 eV to 150 eV and with a dose in a range of 1×10¹² cm⁻² to 5×10¹³ cm⁻², the third impurity concentration of the fourth buried well layer is a concentration defined by an ion implantation energy of 360 eV to 400 eV and with a dose in a range of 1×10¹² cm⁻² to 5×10¹³ cm⁻², and the fourth impurity concentration of the rear diffusion layer is a concentration that is higher than the third impurity concentration, and
the second conductivity type is an N type, the first impurity concentration of the first buried well layer and the second buried well layer is a concentration defined by an ion implantation energy of 280 eV to 320 eV and with a dose in a range of 0.5×10¹² cm⁻² to 5×10¹³ cm⁻², and the second impurity concentration of the diffusion layer for contact is a concentration defined by an energy of 10 eV to 50 eV and with a dose in a range of 1×10¹⁵ cm⁻² to 1×10¹⁶ cm⁻².

3. The semiconductor image sensor device according to claim 1, wherein the silicon support substrate (101) has a thickness of 700 μm to 800 μm, the insulating layer has a thickness of 10 nm to 200 nm, and the SOI layer has a thickness of 10 nm to 1000 nm.
